(19) United States
(12) Patent Application Publication
(10) Pub. No.: US 2013/0328549 A1
(43) Pub. Date: Dec. 12, 2013

(54) ROTATING MOBILE PROBE AND PROBING ROD USING THE SAME

(71) Applicant: Shaw-Lin LIU, Taipei (TW)

(72) Inventor: Shaw-Lin LIU, Taipei (TW)

(73) Assignee: CHUNG INSTRUMENT ELECTRONICS INDUSTRIAL CO., LTD.

(21) Appl. No.: 13/490,612

(22) Filed: Jun. 7, 2012

(51) Int. Cl. G01R 1/067

(52) U.S. Cl. 324/149

(57) ABSTRACT

A probing rod includes a main casing and a rotating mobile probe, and the rotating mobile probe includes a conductive tube, a needle and a rotating mobile structure, and the conductive tube is contained in the main casing; the rotating mobile structure includes an outer thread formed on the needle and an inner thread formed on the conductive tube, and the outer thread and the inner thread are screwed with each other, such that the needle can perform a linear movement with respect to the conductive tube. Therefore, the needle can be moved with respect to the main casing to achieve the effect of adjusting the length of the probe that extends out from the main casing.

### FIELD OF THE INVENTION

The present invention relates to a probing rod, in particular to the probing rod with a rotating mobile probe.

### BACKGROUND OF THE INVENTION

Electric meter is used extensively in many areas. For example, the electric meter can be used for measuring the voltage or current of an electric wire to find a correct power cable in order to perform further constructions or decorations or install equipments for home decoration or renovation. In technological industries, the electric meter can be used for measuring the voltage, current and resistance values of an integrated circuit for the design of the integrated circuit. In some occasions, a probe of a probing rod of the electric meter is required to be extended into a small crevice in order to measure an object to be tested. However, the length of a probing section of present existing probes is too short, so that the probes cannot be extended into the crevice or in contact with the object to be tested. As a result, the voltage, current or resistance value of the object to be tested cannot be measured accurately. Therefore, it is a main subject for the present invention to overcome the aforementioned problems.

In general, the conventional probing rod comprises a probe and a main casing, wherein a probing section is disposed on a side of the probe, and the probe is passed and installed in the main casing, and the probing section is exposed from the main casing, such that the probing section can be contacted with an object to be tested to achieve the effect of measuring a numeric value such as the voltage, current or resistance of the object to be tested.

However, the conventional probing rod still has the following drawbacks. If the object to be tested is situated inside a crevice, and the height of the crevice is longer than the length of the probing section, then the probing section will be unable to reach or contact with the object to be tested, or measure the correct voltage, current or resistance value of the object to be tested. Obviously, the conventional probes require improvements.

### SUMMARY OF THE INVENTION

Therefore, it is a primary objective of the present invention to provide a rotating mobile probe and a probing rod having the probe, wherein an outer thread and an inner thread are engaged with each other, and a needle is turned to perform a linear movement of the needle with respect to a conductive tube, so as to achieve the effect of adjusting the extended length of the needle that extends out of a main casing.

To achieve the aforementioned objective, the present invention provides a rotating mobile probe comprising a conductive tube, a needle and a rotating mobile structure, wherein the rotating mobile structure has an outer thread formed on the needle and an inner thread formed on the conductive tube, and the outer thread and the inner thread are screwed with each other, such that the needle can perform a linear movement with respect to the conductive tube.

To achieve the aforementioned objective, the present invention provides a probing rod with a rotating mobile probe, and the probing rod comprises a main casing and the rotating mobile probe, and the rotating mobile probe comprises a conductive tube, a needle and a rotating mobile structure, and the conductive tube is contained in the main casing, and the rotating mobile structure has an outer thread formed on the needle and an inner thread formed on the conductive tube, and the outer thread and the inner thread are screwed with each other, such that the needle can perform a linear movement with respect to the conductive tube.

The present invention has the following advantages or effects. The needle of the probe can be electrically coupled to a plunger through a spiral spring to enhance the conductive effect between the needle and the signal transmission module, so as to further improve the signal transmission efficiency. In addition, the spiral spring can be used to support the needle and prevent the needle from retracting into the main casing due to the reaction force of the object to be tested, when the probing section of the needle is used for measuring the object to be tested.

### BRIEF DESCRIPTION OF THE DRAWINGS

FIG. 1 is a perspective view of the present invention;

FIG. 2 is a perspective view of a rotating mobile probe of the present invention;

FIG. 3 is an exploded view of a rotating mobile probe of the present invention;

FIG. 4 is a cross-sectional view of the present invention; and

FIG. 5 is a schematic view of an application of the present invention.

### DESCRIPTION OF THE PREFERRED EMBODIMENTS

The details and technical contents of the present invention will become apparent with the detailed description of the following preferred embodiments accompanied with the illustration of the related drawings as follows. However, the drawings are provided for the purpose of illustrating the present invention only, but not intended for limiting the scope of the invention.

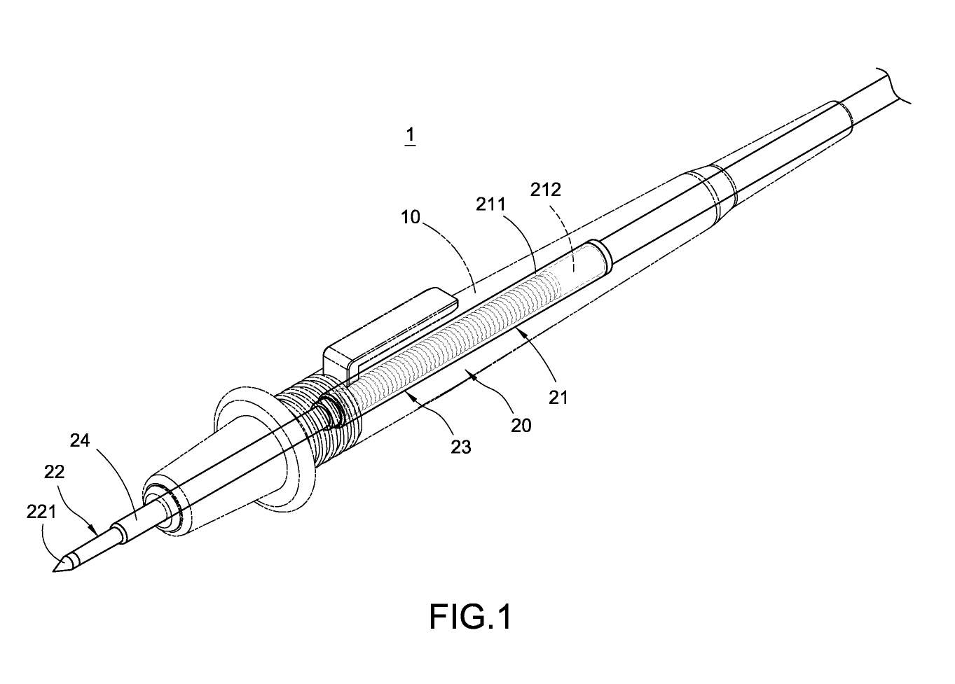

With reference to FIG. 1 for a perspective view of the present invention, the present invention provides a probing rod with a rotating mobile probe, and the probing rod 1 comprises a main casing 10 and a rotating mobile probe 20.

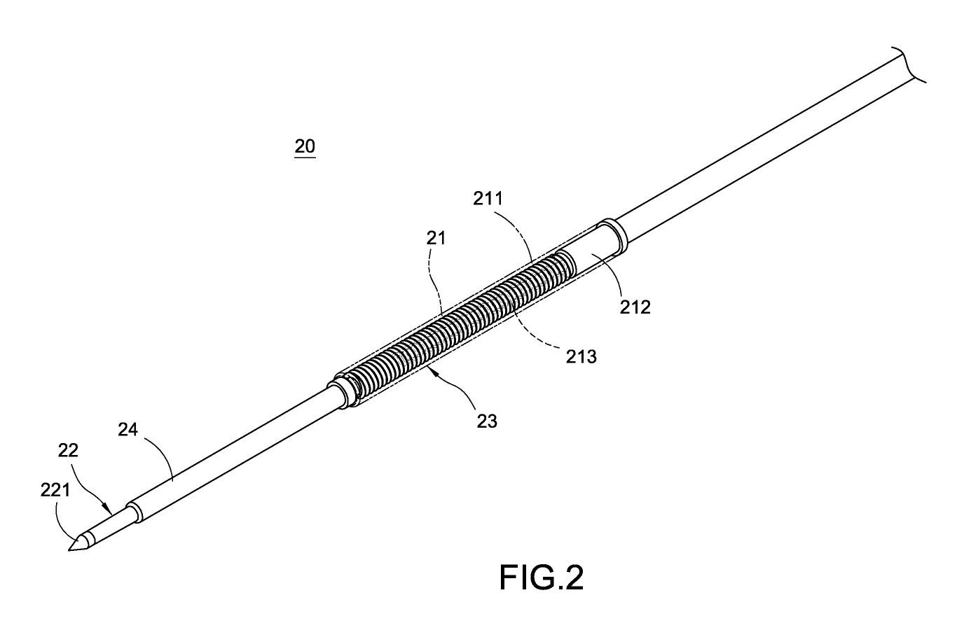

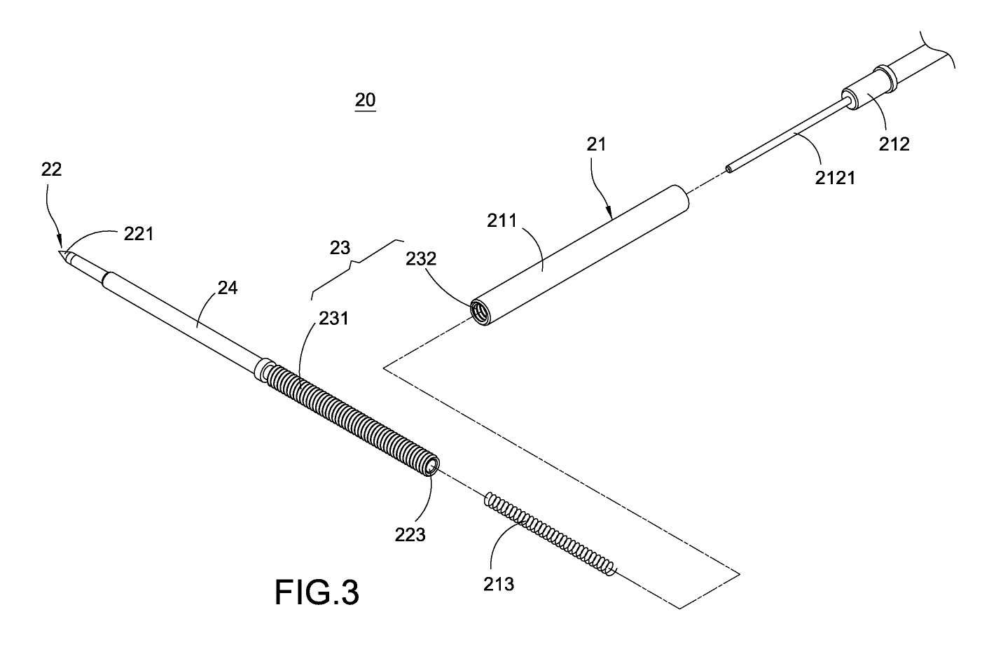

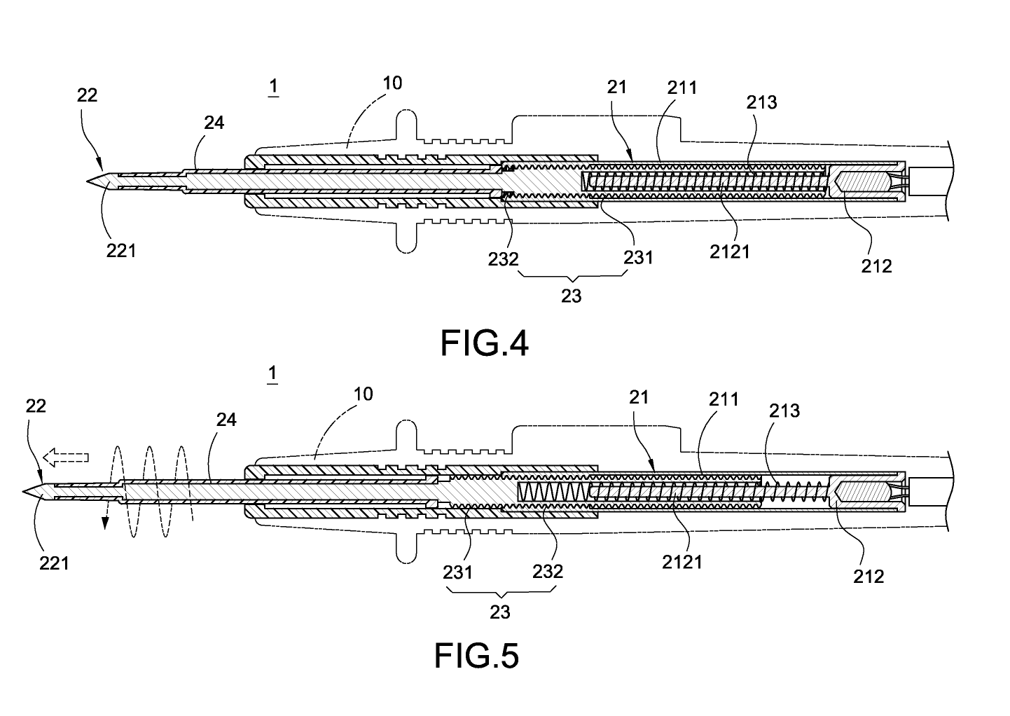

With reference to FIGS. 2 to 4 for a perspective view, an exploded view and a cross-sectional view of a rotating mobile probe of the present invention respectively, the rotating mobile probe 20 comprises a conductive tube 21, a needle 22, a rotating mobile structure 23 and an insulating sleeve 24. The conductive tube 21 is contained in the main casing 10, and the conductive tube 21 includes a copper tube 211, a plunger 212 and a spiral spring 213, and the plunger 212 includes a signal transmission module installed therein, and the plunger 212 has a positioning column 2121. The needle 22 has a probing section 221 and a containing space 223, and the rotating mobile structure 23 has an outer thread 231 and an inner thread 232.

The outer thread 231 of the rotating mobile structure 23 is formed on a side of the needle 22, and a side of the needle 22 with the outer thread 231 is extended and disposed into the copper tube 211, and a side of the rotating mobile structure 23 having the inner thread 232 is formed on an inner wall of the copper tube 211 and proximate to the needle 22, and the outer thread 231 and the inner thread 232 are engaged with each other, such that the needle 22 can perform a linear movement with respect to the copper tube 211. In addition, the needle 22 has an external diameter smaller than the internal diameter of the copper tube 211.

The probing rod 1 further includes a transmission line 30 for transmitting a signal measured by the probing rod 1 to the electric meter, and the plunger 212 of the conductive tube 21 is contained in the copper tube 211 and disposed on a side away from the needle 22, and the copper tube 211 is electrically coupled to the plunger 212, and a side of the plunger 212 away from the copper tube 211 is coupled to the transmission line 30, so that the transmission line 30 is electrically coupled to a signal transmission module in the plunger 212.

The probing section 221 of the needle 22 is disposed on a side away from the outer thread 231, and the containing space 223 is situated on a side of the needle 22 having the outer thread 231, and the insulating sleeve 24 is sheathed on a side of the needle 22 and away from the copper tube 211 and contained in the main casing 10. The probing section 221 of the needle 22 is exposed from the insulating sleeve 24, and the spiral spring 213b is contained in the containing space 223 of the needle 22 and clamped between the needle 22 and the plunger 212. The positioning column 2121 is formed on a side of the plunger 212 and proximate to the needle 22, and the positioning column 2121 of the plunger 212 is passed and installed through the spiral spring 213, and the needle 22 is electrically coupled to the plunger 212 through the spiral spring 213 to enhance the conductive effect between the needle 22 and the plunger 212, so as to enhance the signal transmission efficiency.

With reference to FIG. 5 for a schematic view of an application of the present invention, if a user wants to use the probing rod 1 to measure an object to be tested, the user can rotate the needle 22 to turn the needle 22 out from the copper tube 211, or turn the needle 22 into the copper tube 211, so as to achieve the effect of adjusting the extended length of the probing section 221 of the needle 22. An appropriate length of the probing section 221 can be adjusted to meet the requirements of different occasions, so as to broaden the scope of applicability of the probe for measuring an object to be tested.

In addition, the needle 22 and the copper tube 211 can be coupled by means of the outer thread 231 and the inner thread 232, so that after the needle 22 is rotated to adjust the length of the probing section 221, the principle of engaging the outer thread 231 and the inner thread 232 with each other can be used to fix the needle 22 and the copper tube 211 at relative positions, so as to prevent the needle 22 from retracting into the main casing 10 due to a reaction force of the object to be tested, when the probing section 221 of the needle 22 is used for measuring the object to be tested.

In addition, the spiral spring 213 supports the needle 22 to prevent the needle 22 from retreating into the main casing 10 caused by a reaction force of an object to be tested when the probing section 21 of the needle 22 is used to measure the object to be tested.

In summation of the description above, the present invention improves over the prior art and complies with the patent application requirements, and thus is duly filed for patent application. While the invention has been described by means of specific embodiments, numerous modifications and variations could be made thereto by those skilled in the art without departing from the scope and spirit of the invention set forth in the claims.

What is claimed is:

1. A rotating mobile probe, comprising:
a conductive tube;
a needle; and
a rotating mobile structure, having an outer thread formed on the needle, and an inner thread formed on the conductive tube, and the outer thread and the inner thread being screwed with each other, such that the needle can perform a linear movement with respect to the conductive tube.

2. The rotating mobile probe of claim 1, further comprising an insulating sleeve sheathed on a side of the needle which is away from the outer thread.

3. The rotating mobile probe of claim 2, wherein the needle has a probing section exposed from the insulating sleeve.

4. The rotating mobile probe of claim 2, wherein the conductive tube includes a copper tube, and the inner thread is formed in the copper tube.

5. The rotating mobile probe of claim 4, wherein the conductive tube further includes a plunger contained in the copper tube and electrically coupled to the copper tube.

6. The rotating mobile probe of claim 5, wherein the conductive tube further includes a spiral spring contained in the copper tube and elastically clamped between the needle and the plunger.

7. The rotating mobile probe of claim 6, wherein the needle is electrically coupled to the plunger through the spiral spring.

8. The rotating mobile probe of claim 7, wherein the plunger includes a positioning column protruded from the plunger, and the positioning column is passed and coupled into the spiral spring.

9. A probing rod with a rotating mobile probe, comprising:
a main casing; and
the rotating mobile probe, comprising:
a conductive tube, contained in the main casing;
a needle; and
a rotating mobile structure, including an outer thread formed on the needle, and an inner thread formed on the conductive tube, and the outer thread and the inner thread being screwed with each other, such that the needle can perform a linear movement with respect to the conductive tube.

10. The probing rod with a rotating mobile probe as recited in claim 9, wherein the probe further includes an insulating sleeve sheathed on a side of the needle which is away from the outer thread.

11. The probing rod with a rotating mobile probe as recited in claim 10, wherein the needle has a probing section exposed from the insulating sleeve.

12. The probing rod with a rotating mobile probe as recited in claim 10, wherein the conductive tube includes a copper tube, and the inner thread is formed in the copper tube.

13. The probing rod with a rotating mobile probe as recited in claim 12, wherein the conductive tube further includes a plunger contained in the copper tube, and electrically coupled to the copper tube.

14. The probing rod with a rotating mobile probe as recited in claim 13, wherein the conductive tube further includes a spiral spring contained in the copper tube and elastically clamped between the needle and the plunger.

15. The probing rod with a rotating mobile probe as recited in claim 14, wherein the needle is electrically coupled to the plunger through the spiral spring.

16. The probing rod with a rotating mobile probe as recited in claim 15, wherein the plunger includes a positioning column protruded from the plunger, and the positioning column is passed and coupled into the spiral spring.
